(19) United States
(12) Patent Application Publication
(10) Pub. No.: US 2023/0422450 A1
(43) Pub. Date: Dec. 28, 2023

(54) BOARD AND ELECTRONIC APPARATUS

(71) Applicant: Fujitsu Limited, Kawasaki-shi (JP)

(72) Inventors: Shohei Hashimoto, Yokohama (JP); Takeshi Nishiyama, Kawasaki (JP)

(73) Assignee: Fujitsu Limited, Kawasaki-shi (JP)

(21) Appl. No.: 18/127,879

(22) Filed: Mar. 29, 2023

(30) Foreign Application Priority Data
Jun. 24, 2022 (JP) 2022-101829

(51) Int. Cl. H05K 7/20; H01L 23/40

(52) U.S. Cl. CPC H05K 7/2049; H05K 7/20418; H01L 23/4006

(57) ABSTRACT

A board includes a substrate over which a first heat generator and a second heat generator are mounted, a heat sink which is arranged over the first heat generator and the second heat generator and to which heat from the first heat generator and the second heat generator is dissipated, a presser that presses a first part of the heat sink located over the first heat generator against the substrate via the first heat generator and that secures the first part to the substrate via the first heat generator, and a guide that presses a second part of the heat sink located over the second heat generator against the substrate via the second heat generator, secures the second part to the substrate via the second heat generator, and positions the second part relative to the substrate.

### CROSS-REFERENCE TO RELATED APPLICATION

This application is based upon and claims the benefit of priority of the prior Japanese Patent Application No. 2022-101829, filed on Jun. 24, 2022, the entire contents of which are incorporated herein by reference.

### FIELD

The embodiment disclosed herein is related to a board and an electronic apparatus.

### BACKGROUND

A structure has been disclosed in which a semiconductor package is mounted such that the semiconductor package is provided with reinforcing structures mounted over a motherboard on both sides of the semiconductor package, and a heat sink such as heat dissipation fins is attached to the semiconductor package. The heat sink is in close thermal contact with a flat surface of the semiconductor package via thermally conductive grease. A guide pin is inserted through a through hole provided in the heat sink, a spring of the guide pin is pressed by a flange, and thereby the flange is attached to the guide pin with a screw.

Japanese Laid-open Patent Publication No. 04-186752 is disclosed as related art.

### SUMMARY

According to an aspect of the embodiments, a board includes a substrate over which a first heat generator and a second heat generator are mounted, a heat sink which is arranged over the first heat generator and the second heat generator and to which heat from the first heat generator and the second heat generator is dissipated, a presser that presses a first part of the heat sink located over the first heat generator against the substrate via the first heat generator and that secures the first part to the substrate via the first heat generator, and a guide that presses a second part of the heat sink located over the second heat generator against the substrate via the second heat generator, secures the second part to the substrate via the second heat generator, and positions the second part relative to the substrate.

The object and advantages of the invention will be realized and attained by means of the elements and combinations particularly pointed out in the claims.

It is to be understood that both the foregoing general description and the following detailed description are exemplary and explanatory and are not restrictive of the invention.

### BRIEF DESCRIPTION OF DRAWINGS

FIG. 1 is a perspective view illustrating an interior of an electronic apparatus including a board according to a first embodiment;

FIG. 2 is a perspective view illustrating part of the board according to the first embodiment;

FIG. 3 is a perspective view illustrating the board according to the first embodiment;

FIG. 4 is a front view illustrating the board according to the first embodiment;

FIG. 5 is an enlarged perspective view illustrating part of the board according to the first embodiment;

FIG. 6 is a perspective view illustrating a guide member of the board according to the first embodiment;

FIG. 7 is a perspective view illustrating a state in which attaching of a heat sink is in progress in the board according to the first embodiment; and

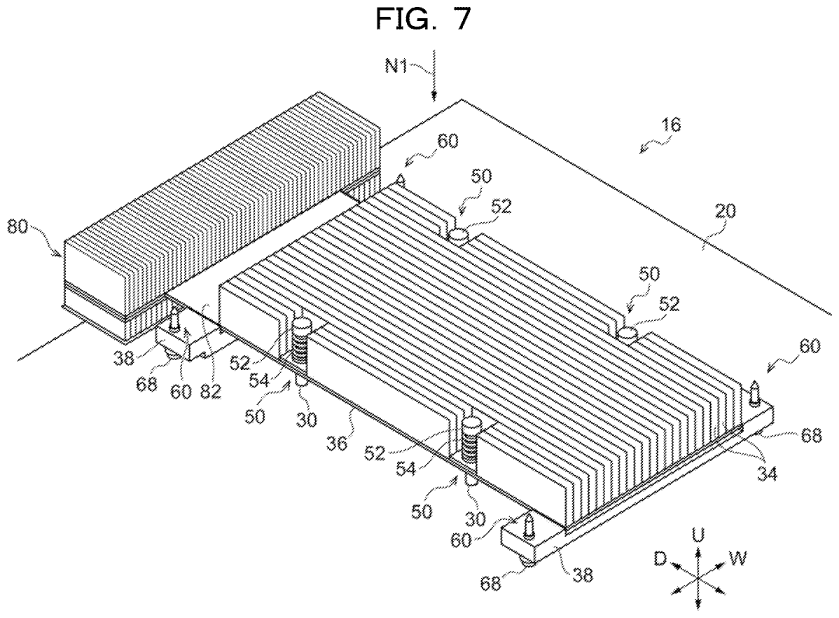

FIG. 8 is a perspective view illustrating a state in which the heat sink has been attached in the board according to the first embodiment.

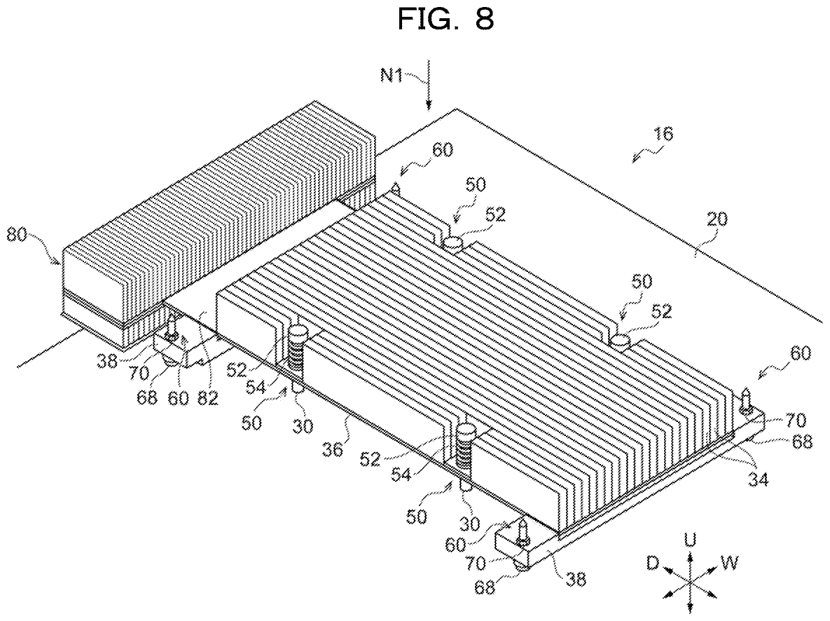

### DESCRIPTION OF EMBODIMENTS

In a case where a structure in which heat is dissipated from a plurality of heat-generating components by a single heat sink is employed in a board in which the plurality of heat-generating components are mounted over a substrate, the heat -generating components may be damaged depending on the types of the heat-generating components unless appropriate pressure is caused to act on each heat generating-component.

An embodiment of techniques of causing appropriate pressure, from a heat sink, to act on each of a plurality of heat-generating components over a substrate is described in detail with reference to the drawings.

### Embodiment

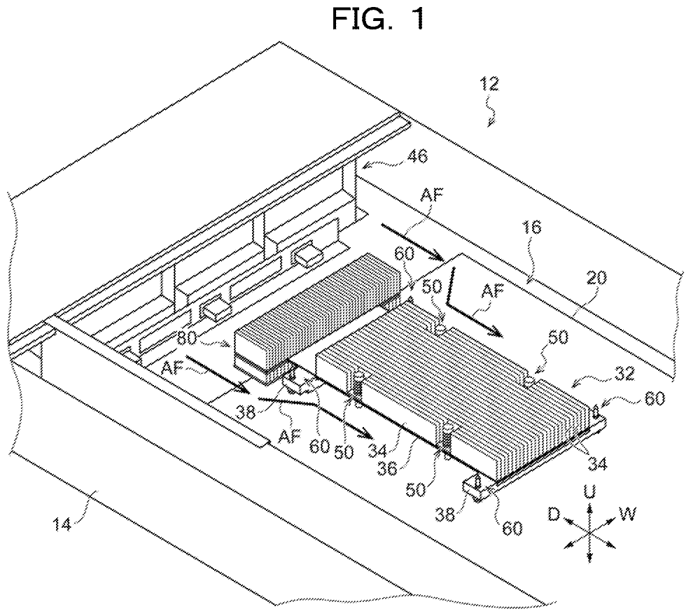

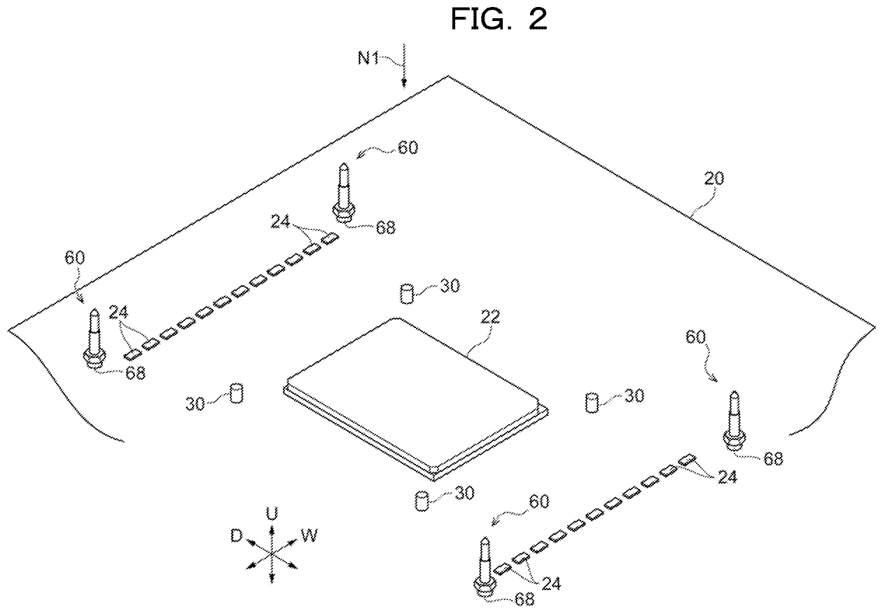

FIG. 1 illustrates part of an electronic apparatus 12 including a board 16. FIG. 2 illustrates the board 16. Although examples of the electronic apparatus 12 may include, for example, an information processing apparatus such as a server or a storage, it is not particularly limiting.

The electronic apparatus 12 includes a housing 14. In the drawings, the width direction, the depth direction, and the height direction of the electronic apparatus 12 are respectively indicated by arrows W, D, and U. In a case where directions are simply referred to as “back” and “front”, these respectively refer to back and front in the depth direction. In a case where directions are simply referred to as “upper” and “lower”, these respectively refer to upper and lower in the up-down direction. According to the present embodiment, the width direction, the depth direction, and the height direction of the electronic apparatus 12 coincide with the width direction, the depth direction, and the height direction of the housing 14 and the board 16. However, these directions do not limit the directions in using the electronic apparatus 12.

A board 16 and a fan 46 are housed in the housing 14. As illustrated in FIG. 2, the board 16 includes a substrate 20. The substrate 20 has a plate shape formed of a material having rigidity and insulating properties.

As illustrated in FIG. 2, a plurality of heat-generating components are mounted over an upper surface of the substrate 20. According to the present embodiment, a processor chip 22 and power supply components 24 are mounted over the substrate 20. The processor chip 22 may be exemplified by, for example, a central processing unit (CPU), a graphics processing unit (GPU), or the like. The processor chip 22 is an example of a first heat-generating component. Examples of the power supply components 24 may include, for example, point-of-load (POL) power supply components. Each power supply component 24 is an example of a second heat-generating component.

According to the present embodiment, a single processor chip 22 is provided and mounted at a central portion of the substrate 20. In contrast, a plurality of the power supply components 24 are provided and arranged in series in the width direction on the back side and the front side of the processor chip 22. Upper surfaces of all the plurality of power supply components 24 are located at the same height position from the upper surface of the substrate 20 and at a lower position than that of an upper surface of the processor chip 22.

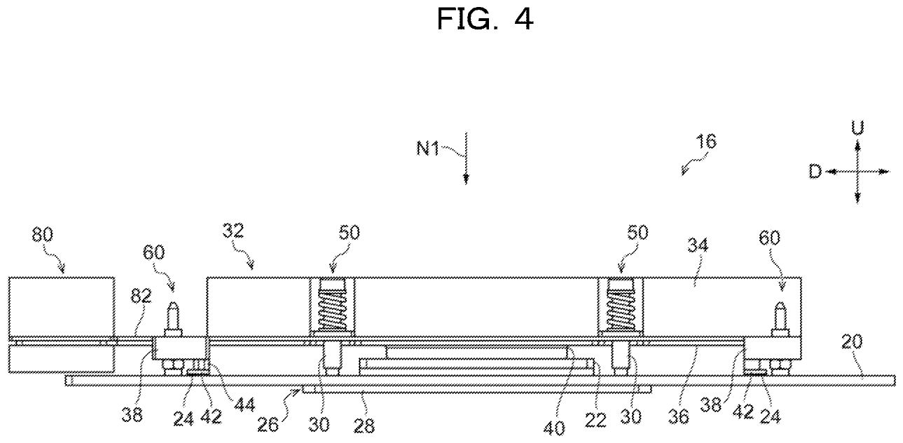

A lower surface of the substrate 20 is an opposite surface from the surface over which the processor chip 22 is mounted. The lower surface of the substrate 20 is provided with a predetermined wiring pattern. As illustrated in FIG. 4, a bolster plate 26 is provided over the lower surface of the substrate 20. The bolster plate 26 includes a reinforcing plate 28 that is formed in a plate shape or a frame shape and a plurality of pins 30 that stand erect over the reinforcing plate 28. The reinforcing plate 28 is secured to the lower surface of the substrate 20 to reinforce the substrate 20. When seen in the direction of the normal to the substrate 20, the reinforcing plate 28 has a greater shape than that of the processor chip 22 in the depth direction and the width direction.

Each pin 30 stands erect from a position around the reinforcing plate 28, extends through the substrate 20, and projects to the upper side of the substrate 20. In a state in which a heat sink 32 is attached to the substrate 20, the pin 30 is inserted through a through hole (not illustrated) of the heat sink 32 and exposed to the upper side of the heat sink 32. When seen in the direction of the normal to the substrate 20 (an arrow N1 direction), four pins 30 are disposed so as to surround the processor chip 22 at positions near the corners of the processor chip 22. A female thread is formed in an upper surface of each pin 30.

The board 16 further includes the heat sink 32. When seen in the direction of the normal to the substrate 20 (the arrow N1 direction), the entirety of the heat sink 32 covers the processor chip 22 and the power supply components 24. The heat sink 32 receives heat of the processor chip 22 and the power supply components 24. The processor chip 22 and the power supply components 24 are cooled when this heat is dissipated from the heat sink 32 to air.

A plurality of heat dissipation fins 34 are provided over an upper surface of the heat sink 32. Each heat dissipation fin 34 is a plate-shaped member extending in the depth direction. The heat dissipation fins 34 are arranged at predetermined intervals in the width direction. As will be described later, wind generated by the fan 46 flows between these heat dissipation fins 34.

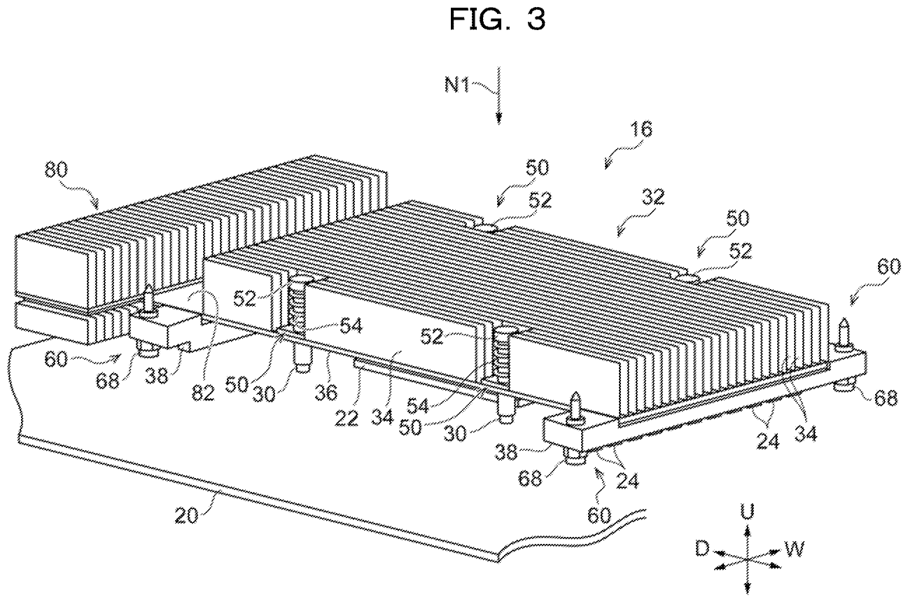

As illustrated in FIG. 3, the heat sink 32 includes a first portion 36 and second portions 38. The first portion 36 is a plate-shaped member. Part of the first portion 36 faces the processor chip 22. The first portion 36 receives heat from the processor chip 22 via grease 40 (see FIG. 4).

According to the present embodiment, when seen in the direction of the normal to the substrate 20 (the arrow N1 direction), the first portion 36 has a depth that covers the row of the power supply components 24 on the back side and the row of the power supply components 24 on the front side.

The second portions 38 are elongated portions extending along a direction in which the power supply components 24 are arranged. According to the present embodiment, since the power supply components 24 are arranged in two rows, two second portions 38 are provided. Each second portion 38 is interposed between the first portion 36 and a corresponding one of the rows of the power supply components 24. The second portion 38 is in direct contact (substantially integrated) with the first portion 36. Part of a lower surface of the second portion 38 faces the power supply components 24 and receives heat from the power supply components 24 via a thermal sheet 42 (see FIG. 4). The heat of the power supply components 24 received by the second portion 38 is further transferred to the first portion 36.

A tapered surface 44 is formed in a lower portion of the second portion 38 such that the tapered surface 44 is inclined toward the center in the width direction as the tapered surface 44 extends from the back side toward the front side. As will be described later, as part of the wind generated by the fan 46 flows from the back side to the front side, the wind also flows inward in the width direction along the tapered surface 44.

The heat sink 32 further includes a plurality of pressing members 50. According to the present embodiment, as illustrated in FIG. 3, when seen in the direction of the normal to the substrate 20 (the arrow N1 direction), four pressing members 50 are disposed so as to surround the processor chip 22 at positions near the corners of the processor chip 22. The heat dissipation fins 34 are formed in a shape that avoids the pressing members 50.

As illustrated in FIGS. 3 and 4, each pressing member 50 include a screw 52 and a spring 54. The screw 52 is screwed into a female thread formed in the upper surface of the pin 30.

The spring 54 is disposed between the head of the screw 52 and the first portion 36. As the screw 52 is screwed into the female thread of the pin 30, the spring 54 is compressed. Thus, a spring force of the compressed spring 54 acts on the first portion 36. Thus, the pressing member 50 presses the first portion 36 against the substrate 20 via the processor chip 22 and secure the first portion 36 to the substrate 20 via the processor chip 22.

The board 16 includes a plurality of guide members 60. According to the present embodiment, as illustrated in FIG. 1, when seen in the direction of the normal to the substrate 20 (the arrow N1 direction), the plurality of guide members 60 are disposed at positions on both sides of each second portion 38 in the longitudinal direction (the width direction of the substrate 20). Two guide members 60 per second portion 38 are disposed, and accordingly, as a whole, four guide members 60 are disposed at the positions around the processor chip 22. Studs 68 is mounted at the positions of the guide members 60 over the substrate 20, and thereby, the guide members 60 are secured to the studs 68.

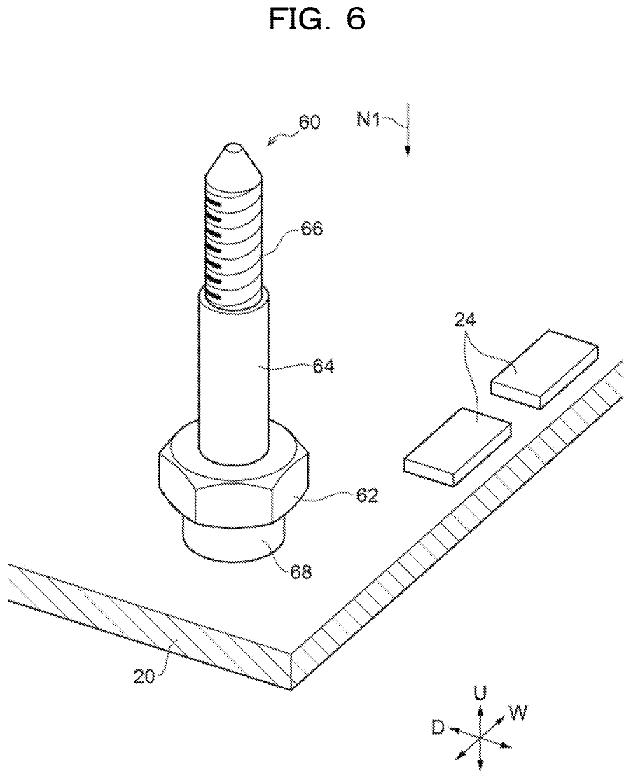

As illustrated in detail in FIG. 6, each guide member 60 includes a support portion 62, an insertion portion 64, and a threaded portion 66. The support portion 62 is secured to a stud 68. The support portion 62 includes a nut that is screwed to a predetermined position in the up-down direction. The nut is a portion that supports the second portion 38 from below. The position of the nut in the up-down direction is adjustable relative to the substrate 20.

The insertion portion 64 is located above the support portion 62 and has a smaller outer diameter than the outer diameter of the support portion 62. Through holes (not illustrated) are formed in the second portions 38 of the heat sink 32 at positions corresponding to the respective guide members 60. An inner diameter of each through hole is smaller than the diameter of the support portion 62 and greater than the diameter of the insertion portion 64. When the heat sink 32 is mounted such that, at each through hole, a corresponding one of the insertion portions 64 is located, the second portions 38 are supported by the support portions 62. When the second portions 38 are supported as described above, the heat sink 32 is positioned in the up-down direction. The position of the heat sink 32 in the up-down direction is adjusted by using the support portions 62 so as to set the second portions 38 at a position where the second portions 38 are pressed against the power supply components 24 with a predetermined pressure.

When the insertion portions 64 of the guide members 60 are inserted through the through holes of the second portions 38, the heat sink 32 is positioned relative to the substrate 20 in the lateral direction (the width direction and the depth direction). For example, since the plurality of guide members 60 are provided, rotation of the heat sink 32 in the in-plane direction may be suppressed.

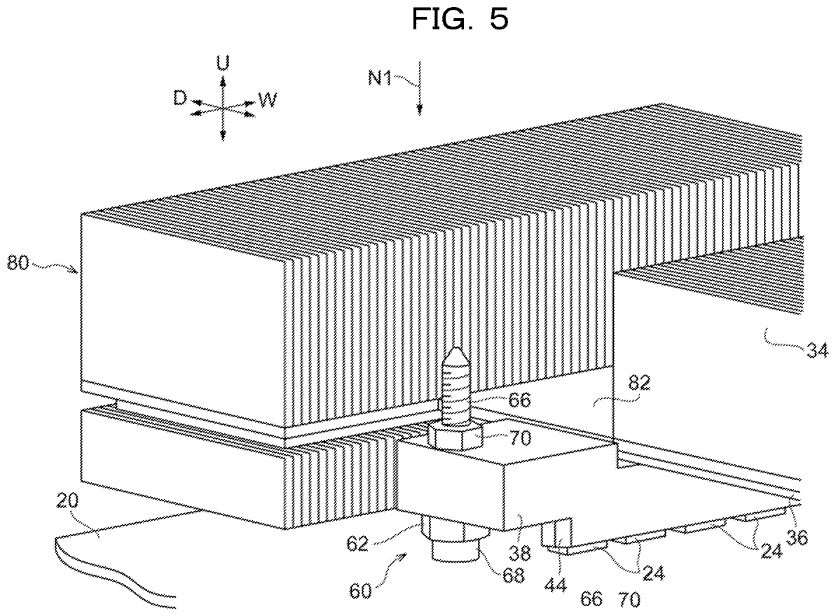

The threaded portion 66 is formed in a columnar shape having a smaller diameter than that of the insertion portion 64. A male thread is formed in an outer circumference of the threaded portion 66. As illustrated in FIG. 5, when a nut 70 is screwed onto the threaded portion 66, the second portion 38 may be clamped between the nut 70 and the support portion 62 in the thickness direction. The threaded portion 66 and the nut 70 are examples of a second screw.

An upper portion of the threaded portion 66 has a frusto-conical shape the diameter of which reduces toward an upper end. This facilitates an operation of inserting the threaded portion 66 into the through hole of the second portion 38.

As illustrated in FIGS. 3 and 4, a radiator 80 is disposed further to the back side than the heat sink 32. The heat dissipation fins 34 and the radiator 80 are coupled to each other by a vapor chamber 82. Part of the heat received by the first portion 36 moves to the radiator 80, and this heat is also dissipated from the radiator 80. According to the present embodiment, the heat sink 32 is configured such that part of the first portion 36 of the heat sink 32 substantially serves as the vapor chamber 82. Accordingly, the heat received by the first portion 36 from the processor chip 22 is efficiently transferred to the heat dissipation fins 34 and the radiator 80.

As illustrated in FIG. 1, the fan 46 is provided on the back side of the board 16 in the housing 14. When the heat dissipation fins 34 are exposed to the wind generated by the fan 46, heat may be dissipated from the heat dissipation fins 34.

Next, a method of attaching the heat sink 32 to the substrate 20 according to the present embodiment and operation of the present embodiment are described.

As illustrated in FIG. 2, the processor chip 22, the power supply components 24, and the studs 68 are mounted over the upper surface of the substrate 20 by using solder and the like. For example, the processor chip 22 is mounted by ball grid array (BGA) coupling or directly mounted by soldering or the like. Alternatively, the processor chip 22 may be mounted over the upper surface of the substrate 20 by using a socket such as a land grid array (LGA). For example, the power supply components 24 are directly mounted over the upper surface of the substrate 20 by soldering. For example, the studs 68 may be soldered to the substrate 20 or mechanically secured by screws or the like.

The guide members 60 are mechanically secured to the studs 68 over the substrate 20. This securing may be achieved by a structure in which the male threads of the studs 68 are screwed into the female threads of the bottom surfaces of the guide members 60 or by bonding with an adhesive or the like instead of or in addition to the screwing. The bolster plate 26 is mechanically secured to the lower surface of the substrate 20.

Next, the grease 40 (see FIG. 4) is applied to the upper surface of the processor chip 22, and the thermal sheets 42 (see FIG. 4) are installed over the upper surfaces of the power supply components 24. The heat sink 32 is installed on the upper side of the processor chip 22 and the power supply components 24. In this state, the insertion portions 64 of the guide members 60 are inserted through insertion holes (not illustrated) of the second portions 38 of the heat sink 32.

The first portion 36 of the heat sink 32 assumes a state in which the first portion 36 abuts against the upper surface of the processor chip 22 via the grease 40. In this state, the screws 52 are screwed into the pins 30 of the bolster plate 26, and the spring forces of the springs 54 are caused to act on the heat sink 32. According to the present embodiment, four pressing members 50 are provided, and the screws 52 are screwed into the pins 30 such that the spring forces of the springs 54 uniformly act on the heat sink 32. Thus, the first portion 36 of the heat sink 32 is pressed against the upper surface of the processor chip 22, and the heat sink 32 is secured to the substrate 20 via the processor chip 22.

Next, the nuts 70 are screwed onto the threaded portions 66 of the guide members 60 from above. When the nuts 70 press the second portions 38 downward, the thermal sheets 42 are compressed between the second portions 38 and the power supply components 24. According to the present embodiment, four guide members 60 are provided, and the nuts 70 are tightened such that pressing forces from the nuts 70 act uniformly. Thus, the second portions 38 of the heat sink 32 are pressed against and secured to the substrate 20 via the power supply components 24. The insertion portions 64 of the guide members 60 are inserted through the through holes of the second portions 38. Thus, the second portions 38 of the heat sink 32 are positioned relative to the substrate 20 in the width direction and the depth direction. Since the second portions 38 of the heat sink 32 are integrated with the first portion 36, the heat sink 32 as a whole is positioned relative to the substrate 20 in the width direction and the depth direction.

As described above, according to the present embodiment, the first portion 36 of the heat sink 32, for example, a portion disposed over the processor chip 22 is pressed by the pressing members 50, and the second portions 38, for example, portions disposed over the power supply components 24 are pressed by the guide members 60. Accordingly, the pressure acting on the processor chip 22 from the heat sink 32 and the pressure acting on the power supply components 24 from the heat sink 32 may be set to be different from each other. Thus, the pressure acting on the processor chip 22 from the heat sink 32 and the pressure acting on the power supply components 24 from the heat sink 32 may be set to be respective appropriate pressures. For example, even in a case where the power supply components 24 that may be damaged by application of high pressure are used, damage to the power supply components 24 may be suppressed by reducing the pressure acting on the power supply components 24 from the heat sink 32.

For example, according to the present embodiment, two types of components which are the processor chip 22 and the power supply components 24 are cooled by the heat sink 32 provided in common to the two types of components. Compared to a structure in which separate heat sinks are respectively provided for these two types of components, efficient cooling may be performed. For example, the processor chip 22 generates a larger amount of heat than that of the power supply component 24. Accordingly, even when a further increase in size of a heat sink for cooling the processor chip 22 is tried, it is difficult to further increase the size of the heat sink in a case where interference with a heat sink for cooling the power supply components 24 occurs. The heat of the heat sink for cooling the processor chip may be transferred to a radiator or the like provided at a separate position from the heat sink. However, also in this case, a heat pipe or a vapor chamber for heat transfer to the radiator may interfere with the heat sink for cooling the electronic components.

In contrast, according to the present embodiment, cooling of the processor chip 22 and cooling of the power supply components 24 are realized an integrated heat sink, for example, a single heat sink 32. Accordingly, the processor chip 22 and the power supply component 24 may be efficiently cooled without the occurrences of, for example, a situation in which the heat sink for cooling the processor chip 22 interferes with the heat sink for cooling the power supply components 24.

The upper surface of the processor chip 22 and the upper surfaces of the power supply components 24 are located at different height positions from the substrate 20. In this case, for example, when a level difference corresponding to this height difference is provided in part of the heat sink, the two types of components having upper surfaces at different levels in height may be cooled by the integrated heat sink. However, even in this case, when the integrated heat sink is simply pressed toward the substrate, substantially the same pressure may act on the processor chip 22 and the power supply components 24.

In a case where two types of components are cooled by an integrated heat sink, when the two types of components are disposed at separate positions, a relative positional deviation between the two types of components may be large. When the relative positional deviation between the two types of components is large as described above, it is difficult to position the heat sink relative to each of the components.

In contrast, according to the present embodiment, the pressure acting on the processor chip 22 from the heat sink 32 and the pressure acting on the power supply components 24 from the heat sink 32 may be set to be different from each other. Thus, damage to the power supply components 24 may be suppressed. In addition, according to the present embodiment, positioning of the heat sink 32 relative to the two types of components which are the processor chip 22 and the power supply components 24 may be realized with high accuracy by using the guide members 60.

As illustrated in FIG. 1, the board 16 in a state in which the heat sink 32 is attached to the substrate 20 is mounted at a predetermined position in the housing 14. When the fan 46 is driven in this state, wind is generated. As indicated by an arrow AF, this wind flows along the heat dissipation fins 34, and the heat of the heat dissipation fins 34 moves to the wind. For example, the heat of the processor chip 22 and the power supply components 24 is transferred to the wind via the heat sink 32, and thereby the processor chip 22 and the power supply components 24 are cooled.

According to the present embodiment, the pressing members 50 include the screws 52. When the screws 52 are tightened, the heat sink 32 is pressed against the substrate 20. Instead of the screws 52, a structure in which, for example, push pins, rivets, or the like are pushed into the pins 30 or the like of the bolster plate 26 may be used. Compared to the structure in which the push pins are used, the structure in which the screws 52 are used facilitates adjustment of the pressing forces and also facilitates strong pressing by increasing the screwing amount of the screws 52.

According to the present embodiment, the pressing members 50 include the springs 54. When the screws 52 are screwed, the springs 54 are compressed, and thereby the spring forces are exerted. With the spring forces, the heat sink 32 is pressed. Compared to a structure without the springs 54, for example, a structure in which the heat sink 32 is directly pressed by the heads of the screws 52 or the like, the heat sink 32 may be strongly pressed with the spring forces. Even in a case where the screws 52 are loosened, as long as the springs 54 are compressed, the heat sink 32 may be pressed with the spring forces.

However, according to the technique disclosed herein, even with a structure in which the pressing members 50 do not include the springs 54, the pressure acting on the processor chip 22 from the heat sink 32 and the pressure acting on the power supply components 24 from the heat sink 32 may be set to be different from each other. For example, when the screwing amount of the screws 52 of the pressing members 50 is adjusted, the pressure acting on the processor chip 22 from the heat sink 32 may be set to be greater than the pressure acting on the power supply components 24 from the heat sink 32.

According to the present embodiment, the bolster plate 26 is provided. Accordingly, the substrate 20 may be reinforced from the lower surface, for example, the side of the opposite surface from the surface over which the processor chip 22 is mounted. Since a structure in which the screws 52 of the pressing members 50 are screwed into the pins 30 of the bolster plate 26 is provided, new members into which the screws 52 are screwed are not desired. In addition, the reinforcing plate 28 of the bolster plate 26 is disposed over the lower surface of the substrate 20. Thus, the heat sink 32 may be attached to the substrate 20 by clamping, in the up-down direction, the heat sink 32 and the substrate 20 between the reinforcing plate 28 and the pressing members 50 disposed over the upper surface of the substrate 20.

According to the technique disclosed herein, the number and positions of the pressing members 50 are not limited. According to the present embodiment, the plurality of pressing members 50 are disposed at the positions around the processor chip 22 in plan view of the substrate 20 (when seen in the arrow N1 direction). The heat sink 32 may be uniformly pressed from the plurality of pressing members 50 around the processor chip 22. Thus, the heat sink 32 may be pressed against the substrate 20 while inclination of the heat sink 32 relative to the substrate 20 may be avoided.

According to the present embodiment, four pressing members 50 are provided, and the pressing members 50 are disposed at the positions of the vertices of the quadrangle in plan view of the substrate 20. Accordingly, compared to a structure in which the pressing members 50 are disposed at positions other than the vertices of the quadrangle, the heat sink 32 may be pressed against the substrate 20 by allowing more uniform forces to act on the heat sink 32.

According to the present embodiment, the heat sink 32 includes the first portion 36 and the second portions 38. The heat sink 32 has a shape having two or more than two portions as described above. Thus, for example, a structure in which the heat sink 32 is in contact with each of a plurality of types of heat-generating components having upper surfaces at different heights over the substrate 20 may be realized.

For example, according to the present embodiment, the upper surfaces of the power supply components 24 are located at a lower position than the upper surface of the processor chip 22. The heat sink 32 includes the first portion 36 and the second portions 38 located below the first portion 36, for example, located close to the substrate 20. Accordingly, a structure that efficiently receives the heat may be realized by allowing the heat sink 32 to be in contact with, via, for example, the grease or the thermal sheets, the two types of the heat-generating components the positions of the upper surfaces of which are at different heights as described above.

According to the present embodiment, guide members 60 include the respective support portions 62, the respective insertion portions 64, and the respective threaded portions 66. With the support portions 62, the heat sink 32 may be supported and positioned in the up-down direction. When the insertion portions 64 are inserted through the insertion holes (not illustrated) of the second portions 38 of the heat sink 32, the heat sink 32 may be positioned in the lateral direction. As described above, since the guide members 60 have portions for positioning the heat sink 32 in the up-down direction and portions for positioning the heat sink 32 in the lateral direction, the heat sink 32 may be reliably positioned. When the nuts 70 are screwed onto the threaded portions 66, a structure in which the heat sink 32 is pressed toward the substrate 20 at the second portions 38 may be realized.

According to the present embodiment, the plurality of power supply components 24 are arranged in series over the substrate 20. The second portions 38 of the heat sink 32 are elongated members along the direction in which the power supply components 24 are arranged. The second portions 38 having an elongated simple shape as described above allow the realization of a structure in which the heat sink 32 receives heat from the plurality of power supply components 24.

According to the present embodiment, for each second portion 38, the guide members 60 are provided at the positions on both sides in the longitudinal direction. For example, positioning and pressing of the second portion 38 having an elongated shape may be performed at positions on both sides in the longitudinal direction.

According to the technique disclosed herein, the number and positions of the guide members 60 are not limited. According to the present embodiment, the power supply components 24 are arranged in series in a plurality of rows (two rows). A plurality of (two according to the present embodiment) second portions 38 of the heat sink 32 are provided in a shape conforming to the respective rows of the power supply components 24. Accordingly, heat may be received from the power supply components 24 in each of the plurality of rows by a corresponding one of the second portions 38 of the heat sink 32.

According to the present embodiment, as illustrated in FIG. 5, the tapered surface 44 is formed in the lower portion of the second portion 38. As part of the wind generated by the fan 46 flows from the back side to the front side, the wind also flows inward in the width direction along the tapered surface 44. For example, the processor chip 22 may be efficiently cooled by causing the wind to flow toward a portion where the processor chip 22 is located or a portion near the portion where the processor chip 22 is located. According to the present embodiment, the radiator 80 located on the back side (upstream side of the wind flow) has a shape projecting outward in the width direction relative to the first portion 36 located on the front side (downstream side of the wind flow). Even when the radiator 80 has such a shape, the wind flows around to the downstream side of the radiator 80. Thus, the components mounted downstream of the radiator 80 may be efficiently cooled.

Although the embodiment of the technique disclosed herein has been described, the technique disclosed herein is not limited to the above description. Of course, in addition to the above description, the technique disclosed herein is able to be varied in a variety of manners and embodied without departing from the gist thereof.

All examples and conditional language provided herein are intended for the pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although one or more embodiments of the present invention have been described in detail, it should be understood that the various changes, substitutions, and alterations could be made hereto without departing from the spirit and scope of the invention.

What is claimed is:

1. A board comprising:
a substrate over which a first heat generator and a second heat generator are mounted,
a heat sink which is arranged over the first heat generator and the second heat generator and to which heat from the first heat generator and the second heat generator is dissipated,
a presser that presses a first part of the heat sink located over the first heat generator against the substrate via the first heat generator and that secures the first part to the substrate via the first heat generator, and
a guide that presses a second part of the heat sink located over the second heat generator against the substrate via the second heat generator, secures the second part to the substrate via the second heat generator, and positions the second part relative to the substrate.

2. The board according to claim 1, wherein the presser presses the heat sink against the substrate when a screw is tightened.

3. The board according to claim 2, further comprising:
a spring that exerts a spring force to press the heat sink when the screw is tightened.

4. The board according to claim 2, further comprising:
a bolster plate that includes
a reinforcing plate that is provided over an opposite surface from a surface over which the first heat generator is mounted in the substrate to reinforce the substrate, and
a pin that extends through the substrate from the reinforcing plate to the surface over which the first heat generator is mounted,
wherein the screw is screwed into the pin.

5. The board according to claim 1,
wherein a plurality of pressers are arranged at positions around the first heat generator in plan view of the substrate, the plurality of pressers including the presser.

6. The board according to claim 5,
wherein the plurality of pressers are arranged at positions of vertices of a quadrangle in the plan view.

7. The board according to claim 1,
wherein the heat sink includes
a first portion that faces the first heat generator and that receives the heat of the first heat generator, and
a second portion that is interposed between the first portion and the second heat generator, that receives the heat from the second heat generator, and that transfers the heat to the first portion.

8. The board according to claim 7,
wherein, from the substrate, a height of an upper surface of the second heat generator is lower than a height of an upper surface of the first heat generator, and
wherein the second portion is provided between the upper surface of the second heat generator and the first portion.

9. The board according to claim 8,
wherein the guide includes
a supporter that supports the second portion over the substrate,
an inserter that is inserted through a through hole formed in the second portion, and
a second screw that presses, in a state in which the inserter is inserted through the through hole and the second portion is supported by the supporter, the second portion toward the supporter.

10. The board according to claim 7,
wherein a plurality of second heat generators are arranged over the substrate in series, the plurality of second heat generators including the second heat generator, and
wherein the second portion includes an elongated shape along an arrangement direction in which the plurality of second heat generators are arranged in series.

11. The board according to claim 10,
wherein a plurality of guides are provided at positions on both sides, in the longitudinal direction, of the second portion formed in the elongated shape, the plurality of guides including the guide.

12. The board according to claim 10,
wherein the plurality of second heat generators are mounted over the substrate and arranged in series in a plurality of rows, and
wherein a plurality of second portions are each provided along a corresponding one of the plurality of rows, the plurality of second portions including the second portion.

13. The board according to claim 10,
wherein the second portion includes a tapered surface that extends toward a center in a longitudinal direction as the tapered surface extends toward a downstream side in a flow direction of wind from a fan.

14. An electronic apparatus comprising:
a board that includes
a substrate over which a first heat generator and a second heat generator are mounted,
a heat sink which is arranged over the first heat generator and the second heat generator and to which heat from the first heat generator and the second heat generator is dissipated,
a presser that presses a first part of the heat sink located over the first heat generator against the substrate via the first heat generator and that secures the first part to the substrate via the first heat generator, and
a guide that presses a second part of the heat sink located over the second heat generator against the substrate via the second heat generator, secures the second part to the substrate via the second heat generator, and positions the second part relative to the substrate;
a fan that generates wind toward the heat sink; and
a housing in which the board and the fan are arranged.
